(19) United States
(12) Patent Application Publication
(10) Pub. No.: US 2002/0121365 A1
(43) Pub. Date: Sep. 5, 2002

(54) Radial folded fin heat sink

(76) Inventor: Kazimierz L. Kozyra, Olympia, WA (US)

Correspondence Address: TROP PRUNER & HU, PC, 8554 KATY FREEWAY, SUITE 100, HOUSTON, TX, 77024, US

(21) Appl. No.: 09/800,120

(22) Filed: Mar. 5, 2001

(51) Int. Cl. H05K 7/20; H01L 23/26; F28F 7/00

(52) U.S. Cl. 165/185; 165/80.3; 174/16.3; 361/704

(57) ABSTRACT

A heat sink for cooling a microelectronic device, and methods of manufacturing and operating the heat sink. The heat sink includes a plurality of fins, folded from a strip of thermally conductive material, arranged in a radial pattern. A fan may be disposed at a center of the radial pattern to direct airflow radially outward over the folded fins.

### BACKGROUND OF THE INVENTION

1. Technical Field of the Invention

The present invention relates generally to heat sinks for cooling semiconductor devices or the like, and more specifically to an improved fin structure for such.

2. Background Art

Heat sinks are known in a variety of configurations, both with and without fans. Heat sink designers struggle to balance thermal efficiency against manufacturing cost. Finned heat sinks use a number of fins to increase surface area and thereby improve thermal performance. Fins are generally formed by casting or by machining, both of which contribute significantly to manufacturing cost.

U.S. Pat. Nos. 5,785,116 and 5,975,194 describe heat sinks with fins radially arranged about a central fan, to improve thermal performance and noise generation.

What is desired is a radial fin heat sink which has reduced manufacturing cost but which offers adequate thermal performance.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 shows one embodiment of a folded fin heat sink.

FIG. 2 shows another embodiment of a folded fin heat sink, including a collar.

FIG. 3 shows another embodiment of a folded fin heat sink, including a fan mounted within the folded fins.

FIG. 4 shows airflow through the folded fin heat sink shown in FIG. 3, and shows additional details of a base of the folded fin heat sink.

FIG. 5 shows another embodiment of a folded fin heat sink, including a fan mounted atop the folded fins.

FIG. 6 shows airflow through the folded fin heat sink shown in FIG. 5, and shows additional details of a base of the folded fin heat sink.

FIG. 7 shows another embodiment of a base for a folded fin heat sink.

FIG. 8 shows another embodiment of a folded fin heat sink, having two folded fin cores.

FIG. 9 shows another embodiment of a folded fin heat sink, having improved airflow at its center.

FIG. 10 shows one embodiment of a sheet for forming a folded fin heat sink such as that shown in FIG. 9.

FIG. 11 shows another embodiment of a sheet for forming a folded fin heat sink such as that shown in FIG. 9.

FIG. 12 shows one embodiment of a folded fin heat sink such as may be formed from the sheet of FIGS. 10 or 11.

FIG. 13 shows another embodiment of a folded fin heat sink such as may be formed from the sheet of FIGS. 10 or 11.

FIG. 14 shows another embodiment of the folded fin heat sink in which the tops of the folded fins are open.

### DETAILED DESCRIPTION

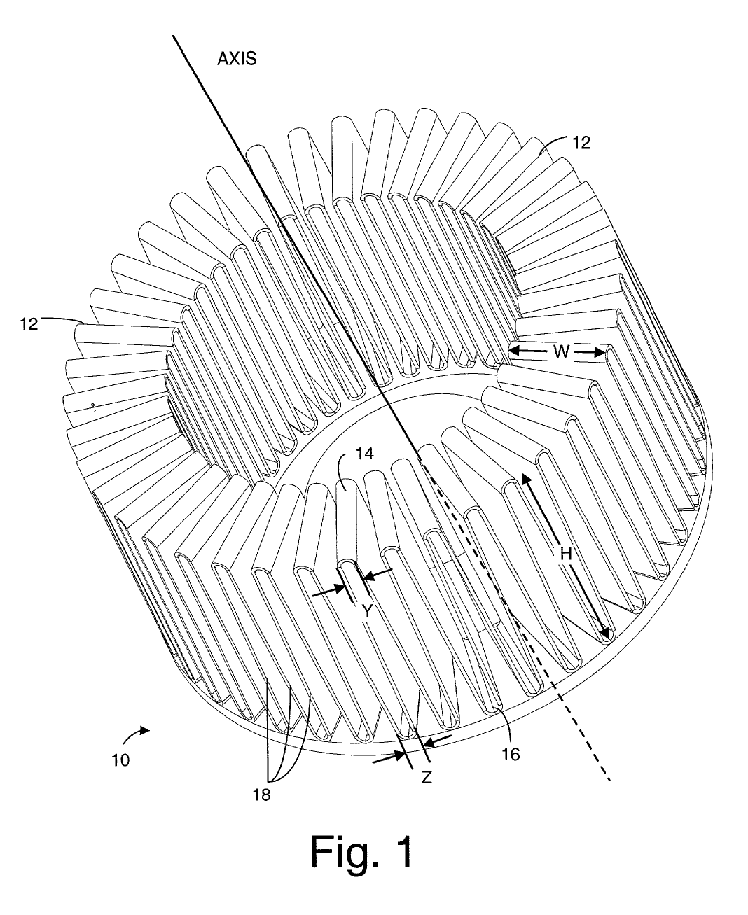

FIG. 1 illustrates one embodiment of the folded fin heat sink 10 of the present invention. The folded fin heat sink includes one or more folded fin members 12 arranged in a radial orientation generally about a center axis of the heat sink. In some embodiments, the folded fin member may be constructed as one unitary member, while in others it may be constructed as two or more members which may optionally be joined to each other. In other words, the entire group of folded fins may be constructed from one piece, or from two or more pieces.

The folded fin member includes a plurality of fins 18 having a height H and a width W. In one embodiment, the fins all have substantially the same height and width, while in other embodiments, the various fins may have differing heights and/or widths.

In various embodiments, the folded fin member may be folded so as to have laterally extending top segments 14 of dimension Y, or a laterally extending bottom segments 16 of dimension Z, or both. Inclusion of the laterally extending segments serves to provide spacing between adjacent fins, to improve airflow, albeit at the expense of reducing the total number of fins.

Those of skill in the art will understand how to select appropriate height H, width W, top dimension Y, and bottom dimension Z, as well as the overall radius of the heat sink, the material from which to make the folded fins, the thickness of that material, and so forth, to balance the thermal performance, size, cost and so forth of the heat sink for usage in a given application.

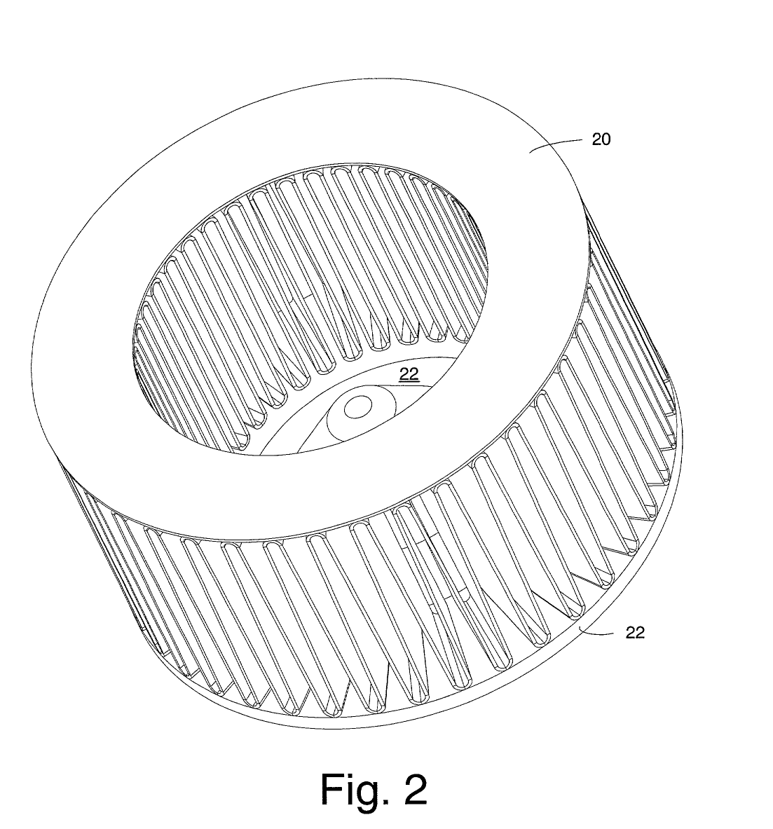

FIG. 2 illustrates the optional addition of a cap 20 and a base 22. The cap may serve to stabilize the fins and keep them from being easily bent, and may offer somewhat increased surface area for thermal transfer. It may also serve to direct airflow. The base may serve as a primary thermal interface between the folded fins and the device (not shown) to be cooled.

The folded fins, the cap, and the base may, in some embodiments, be constructed of metals such as copper or aluminum. In one embodiment, the base is a copper alloy and the fins are an aluminum alloy. In some embodiments, the folded fins may be brazed to the base to improve thermal transfer from the base to the folded fins. In other embodiments, less expensive methods such as epoxy may be used to affix the folded fins to the base. In the least expensive embodiments, the folded fins could simply be touching the base, and could be held in place by, for example, being held captive between the cap and base. The skilled engineer will understand how to make appropriate cost/performance tradeoffs for the particular application at hand.

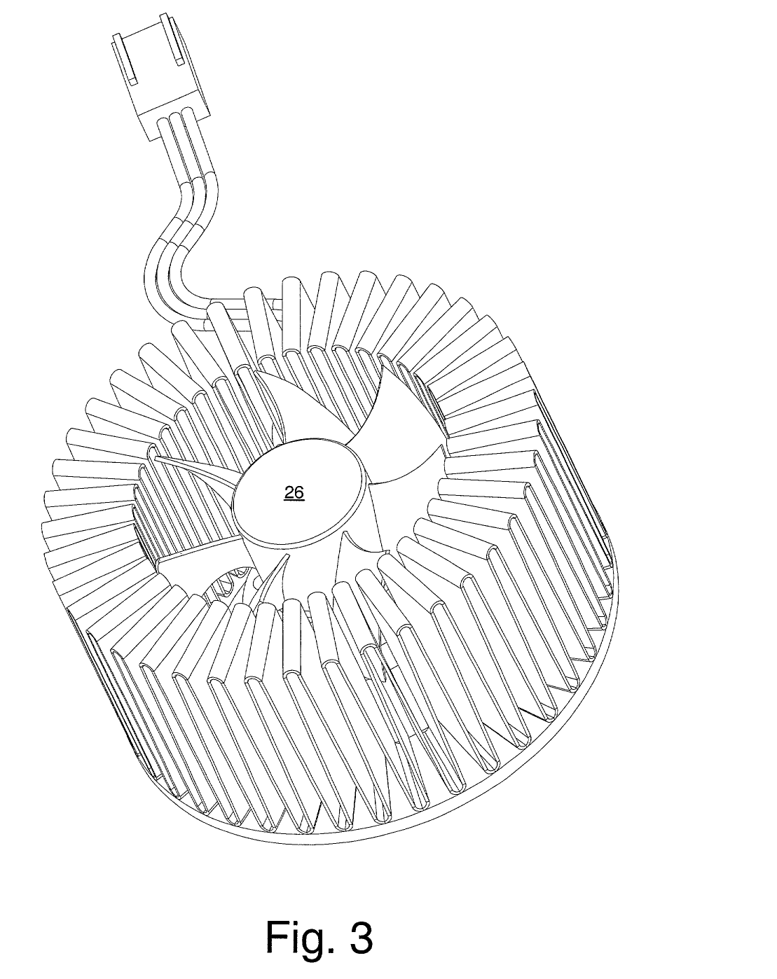

FIG. 3 illustrates the addition of a fan 26 to the heat sink. In some such embodiments, a cap (not shown) may be added, and its inner and outer diameters selected, to appropriately direct airflow, such as to minimize recirculation.

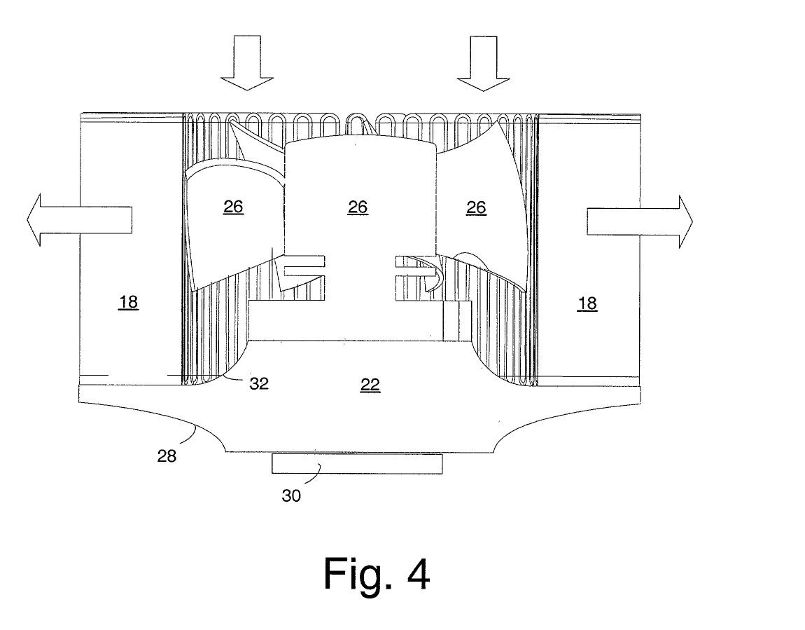

FIG. 4 illustrates the fan-equipped radial folded fin heat sink in cross-section. The fan 26 is disposed within the folded fins 18, and is mounted to the base 22. The base is thermally coupled to the device 30 which is to be cooled, such as a semiconductor or other microelectronic device. The base may in some cases ride on a layer of thermal grease (not shown) which serves to improve thermal transfer by filing in tiny voids which are due to irregularities in the mating surfaces of the base and/or the microelectronic device.

In some embodiments, the fan may draw air in, in a generally axial direction, and expel it outward through the folded fins, as suggested by the arrows. In other embodiments, this flow may be reversed, as the application indicates.

In some embodiments, it may be found desirable to shape the top and/or bottom surfaces of the base. It has been found that overall thermal conductivity depends in some measure upon the thickness of the central region of the base, generally about the microelectronic device, while maintaining that thickness toward the perimeter does not proportionately contribute to overall thermal conductivity. But thickness does contribute directly to weight, and thickness at the perimeter more than linearly contributes to stress on the microelectronic device under shock or vibration. Thus, by having a beveled or otherwise reduced outer portion 32 of the upper surface, and a beveled or otherwise reduced outer portion 28 of the lower surface, the weight of the base is reduced without significantly reducing thermal performance.

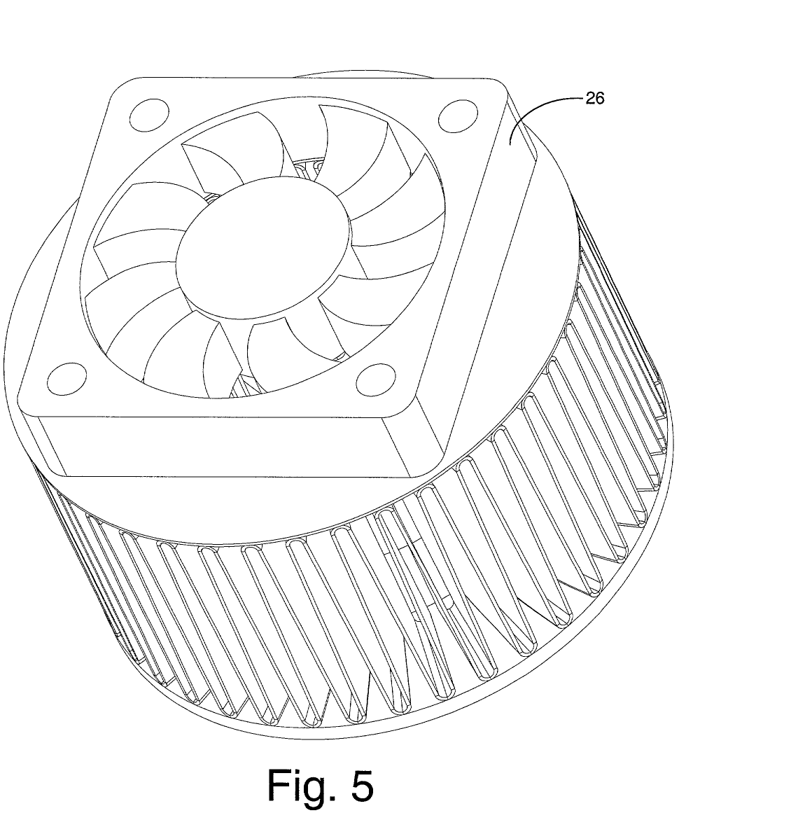

FIG. 5 illustrates another embodiment of the fan-equipped radial folded fin heat sink, in which the fan 26 is mounted externally to the folded fins rather than within their dimensions. In some embodiments, a hybrid of the embodiments of FIGS. 4 and 5 could be used, in which, for example, the motor of the fan is located external to the folded fins, while the propeller blades or other air-moving apparatus is located within the dimensions of the folded fins. In some embodiments, the fan blades may be partly within the folded fin structure and partly outside it. In some embodiments, circulation devices other than fans may be employed, such as blowers or jets.

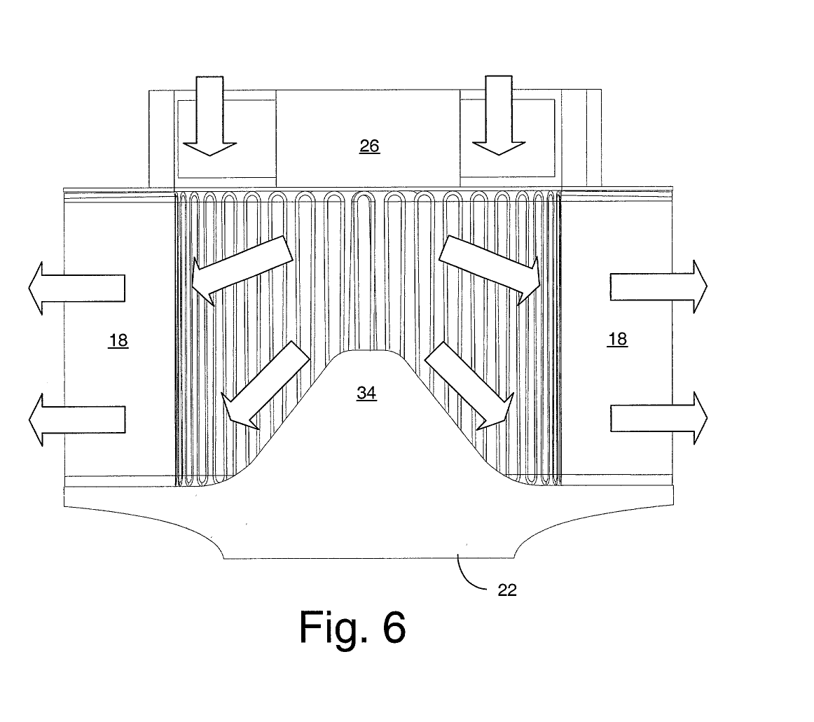

FIG. 6 illustrates one embodiment of a base 22 which may be utilized in conjunction with the externally located fan. In some such applications, airflow and thermal performance may be increased by fabricating the base so as to give it a raised, central portion 34. In some embodiments, this raised, central portion may be substantially conical. The reader will appreciate that the folded fins 18 shown in FIG. 6 are not coupled to the conical section, but are merely seen as being behind it. The skilled person will be able to select an appropriate shape of the central portion, based upon the application's thermal and cost and weight requirements.

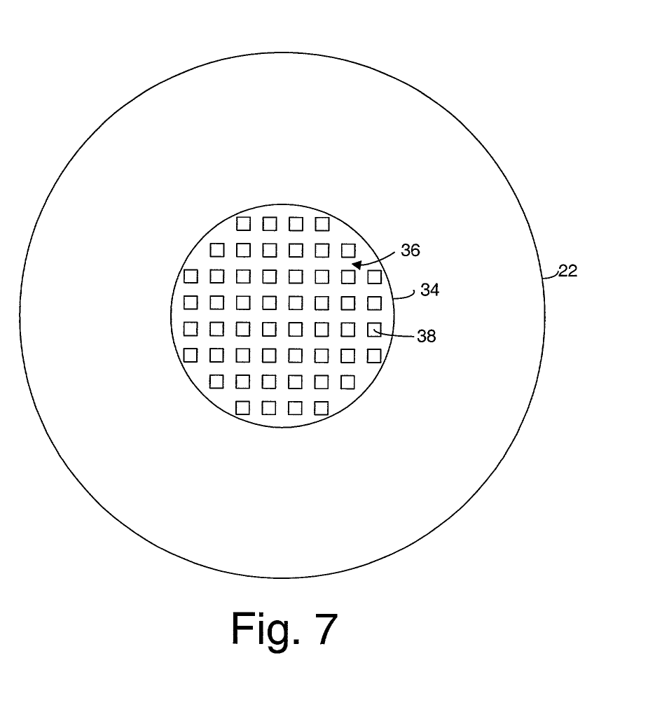

FIG. 7 illustrates another embodiment of the conical central portion 34, shown in top view. In this embodiment, the central portion 34 of the base 22 has been machined or otherwise fabricated to include one or more channels 36 between two or more central portion members 38. In one such embodiment, the channels are cut in two directions, leaving rectilinear posts as the central portion members. This increases the surface area of the central portion 34. In other embodiments, these posts could be formed with, for example, round cross section.

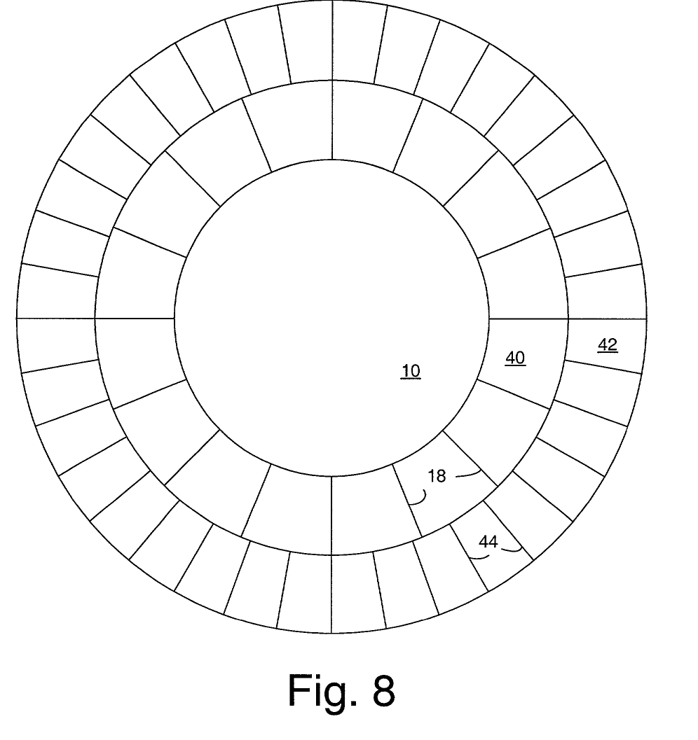

FIG. 8 illustrates, in top view, another embodiment of the radial folded fin heat sink, in which two or more rings 40, 42 of folded fins are utilized. In any radial configuration, the intra-fin spacing is smaller at the fins' inner edges than at their outer edges. One advantage of the multiple-ring embodiment is that it allows for a re-spacing to increase total folded fin surface area. In other words, the outer ring can include more total fins than the inner ring, without violating a minimum intra-fin spacing requirement. The inner ring 40 has fins 18 at a given spacing, and the outer ring 42 has fins 44 at a spacing which is tighter than the spacing at the outer edge of the inner ring's fins 18.

Thermal conductivity is increased in areas of flow and thermal boundary layer development. Once a boundary layer has formed or fully developed and laminar flow is established, thermal conductivity is reduced. By breaking the folded fins into multiple rings, it may in some embodiments be possible to increase the total surface area of boundary layer development. In such cases, it will be desirable to select relative spacings such that the number of lined-up folded fins is minimized, as between folded fins of adjacent rings.

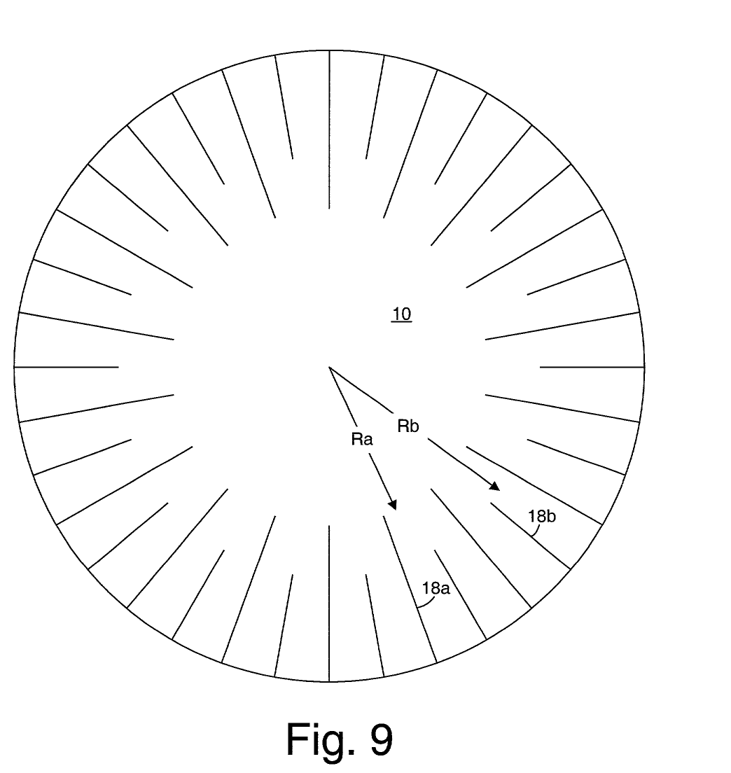

FIG. 9 illustrates, in top view, another embodiment of a radial folded fin heat sink, which addresses the issue of minimum inner spacing. For a given number of radial folded fins of a given thickness, as those fins are extended inward, the spacing between them decreases. At some point, there may not be enough space to provide adequate airflow for a given application. However, backing the inner edge away from the center has the effect of reducing the folded fins' surface area. One solution, shown in FIG. 9, is to utilize folded fins 18a, 18b which extend to different distances Ra, Rb from the center. One embodiment employs folded fins of differing width (W, as shown in FIG. 1). Sufficient space is maintained between adjacent fins 18a that extend to the inner distance Ra, yet the other fins 18b contribute significantly to the total surface area. While, for simplicity, only two such sizes are shown, any number of sizes may be utilized, in a variety of configurations.

Furthermore, while FIG. 9 illustrates an embodiment in which every second fin ends a greater distance from the axis than does its neighbors, other embodiments are within the scope of this invention. For example, there may be multiple different lengths. Or, each folded fin in a pair may share a common width, with alternating pairs being of different width.

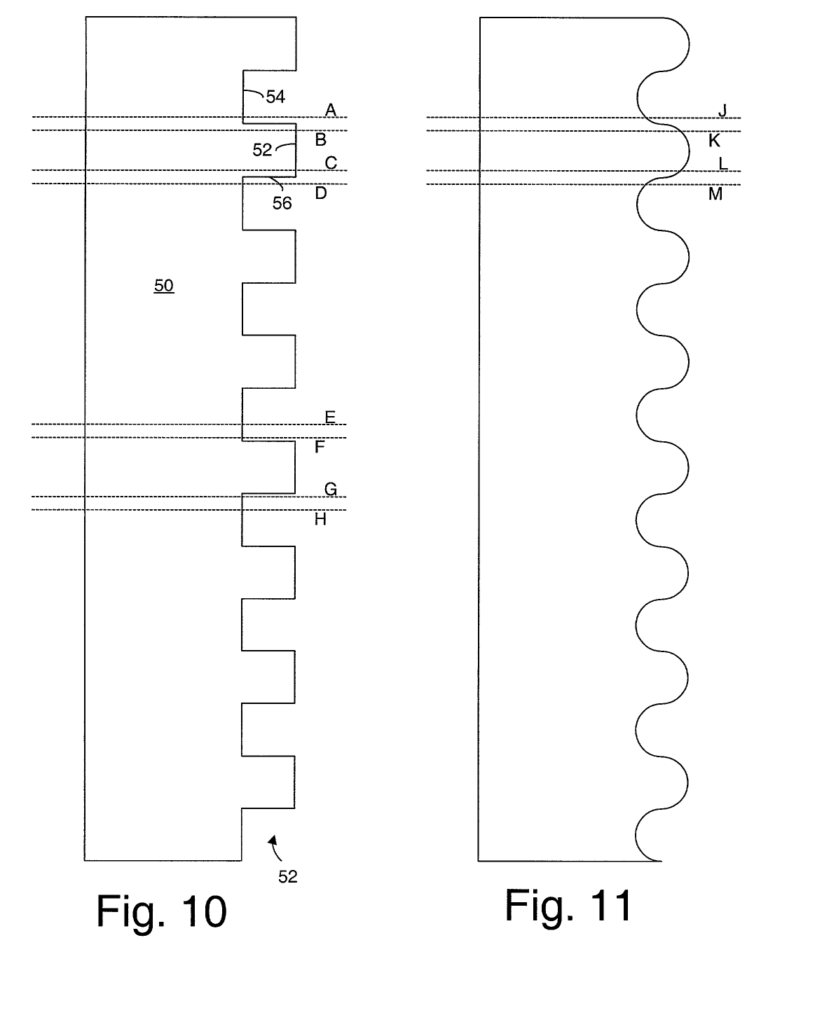

FIG. 10 illustrates a strip of material 50 which may be utilized in manufacturing the folded fins of FIG. 9. The strip includes a toothed or serrated edge 52 which forms the inner edges of the folded fins. In one embodiment, the strip is folded at the dashed lines A-D, which in one embodiment surround respective edges of the serration. The material between two adjacent folds A, B forms the laterally extending top segment (14 in FIG. 1), while the material between two other adjacent folds C, D forms the laterally extending bottom segment (16 in FIG. 1), or vice versa. The material between adjacent folds B, C of respective adjacent pairs of folds forms the folded fin itself (of dimension H in FIG. 1) and has an inner edge 52. The material between the fold D and a fold A of a next set of folds (not shown) would form the next folded fin, and has an inner edge 54. The first inner edge 52 forms the fin which extends more toward the center of the heat sink, while the second inner edge 54 forms the fin which stops short of its neighboring fins. While only two depths of fins are shown in FIG. 10, the reader will appreciate that other depths can readily be produced using this same method.

The reader will notice that the fold pairs A, B and C, D each encompasses a portion of the edge of the material where the depth transition is made. In another embodiment, illustrated at fold pairs E, F and G, H, the folds may be made outside the transition points. In such embodiments, the teeth or serrations will not have a 50:50 “duty cycle”.

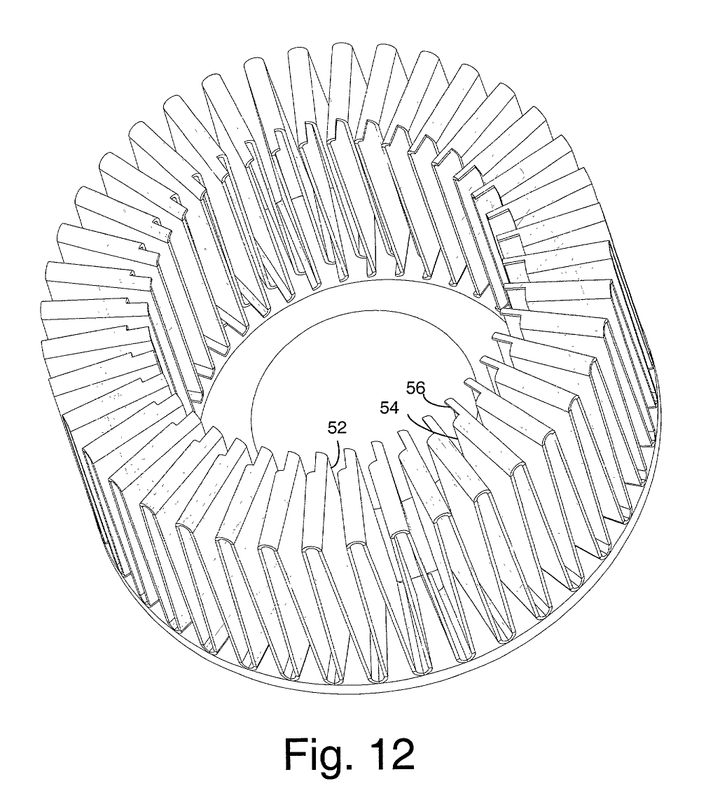

FIG. 11 illustrates yet another embodiment of the strip of material, in which the serrations are not square. In one such embodiment they may have a sinusoidal shape. In other embodiments, other shapes may be used. The fold pairs J, K and L, M may be positioned as with fold pairs A,B and C,D, or as with fold pairs A, B and C, D in FIG. 10.

In some applications, it may not be necessary that the entire vertical dimension (H of FIG. 1) of adjacent fins be completely one length (to Ra or to Rb in FIG. 8). In such applications, the rounded shape of FIG. 11 may be suitable.

Other edge shapes are within the scope of this invention. For example, the edge may be generally saw-toothed but have rounded transitions between the teeth, rather than the 90° angles shown in FIG. 10.

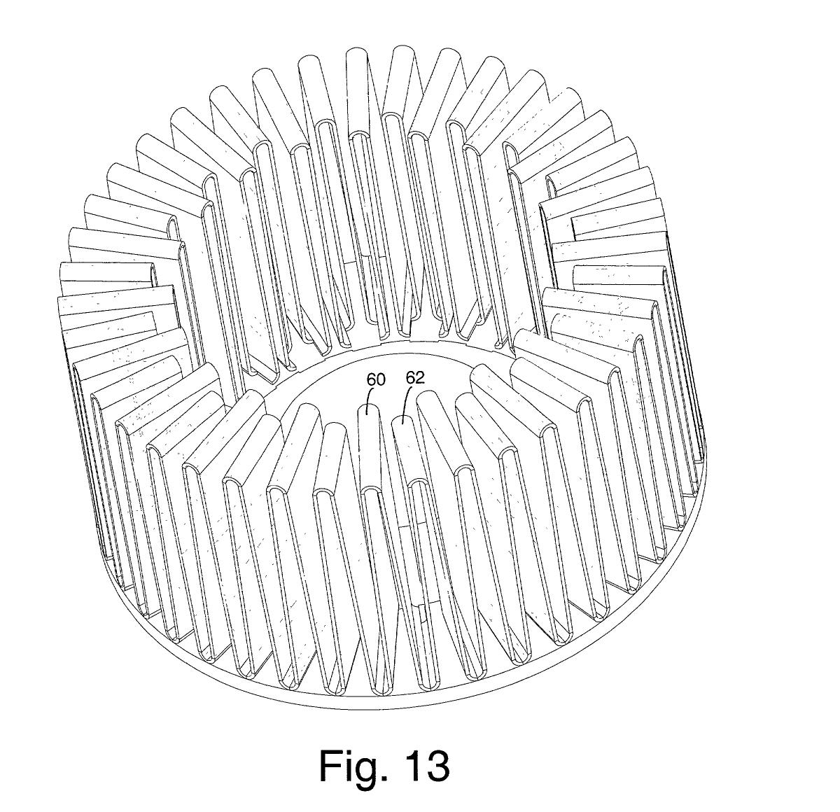

FIG. 12 illustrates a folded fan heat sink made from the strip of FIG. 10 and folded at lines A-D in FIG. 10. The edge 56 of the tooth in FIG. 10 is included within the laterally extending top segment of the folded fins in FIG. 12, while the longitudinal edges 54 and 56 in FIG. 10 become the centermost edges of respective folded fins. (For ease in illustration, the edge 52 is shown for a different tooth in FIG. 12.)

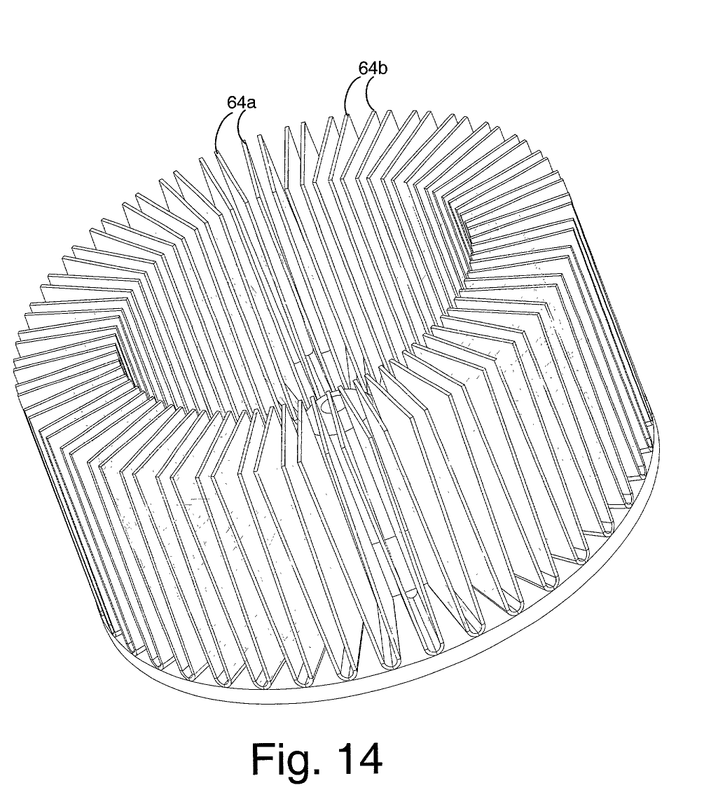

FIG. 13 illustrates an alternative embodiment, in which the strip is folded differently, resulting in a first folded fin pair 60 extending farther toward the axis than the fins of a second folded fin pair 62. Each of the fins of any given pair are of a substantially same width.

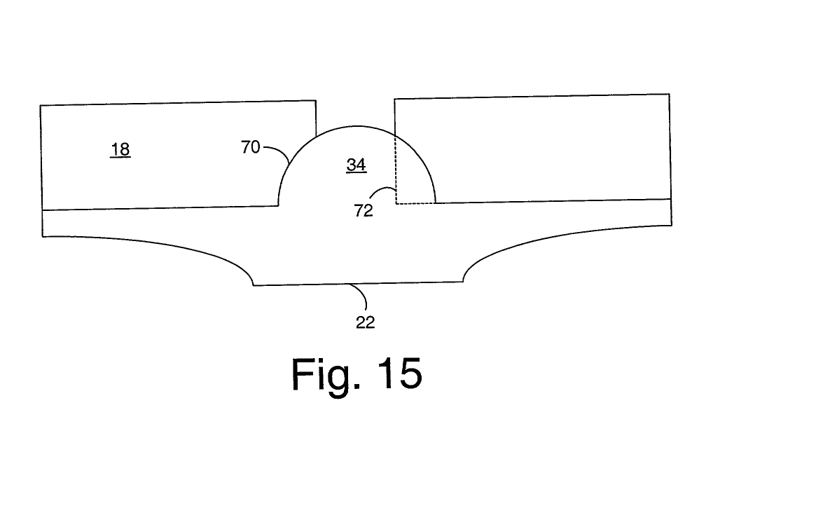

FIG. 14 illustrates another embodiment of the folded fin heat sink, in which the respective folded fin pairs are separate from each other. One method of fabricating this embodiment is to separately bend the pairs and separately affix them to the base. Another method is to fabricate them as a ring, affix them to the base, and remove the laterally extending top segments to separate the pairs. This embodiment may provide improved downward airflow, as both sides of all fins are exposed from the top, rather than having the laterally extending top segments blocking downward airflow between every other pair of adjacent fins.

FIG. 15 illustrates yet another embodiment, in which the folded fins 18 are shaped to allow them to contact the raised central portion 34 of the base 22. This permits greater fin surface area. In some such embodiments, the fins may end short of the axis, leaving room for a small fan. In other embodiments, the fins may extend substantially to the axis.

One method of fabricating such an embodiment as shown in FIG. 15 is to fabricate the folded fins from an appropriately-shaped strip of material having a complex edge. Another is to fabricate the folded fins from a strip which is generally rectangular or which is substantially as shown in FIGS. 10 or 11, and to slot the raised central portion of the base to permit insertion of the fins into it, as suggested by the dashed line 72.

Finally, the reader will appreciate that a variety of manufacturing methods may be employed. In one method, the strip of material is folded while in a substantially linear configuration, and the resulting linear folded fin is bent around a mandrel to give it its radial configuration. In another method, a plurality of individual fins may be separately affixed to the base without any folding. In another, a plurality of strips are folded and affixed to the base in an N-agonal arrangement such that not all of the fins are strictly radial but the overall arrangement is substantially radial. In another, individual fin pairs may be folded from strips and separately affixed to the base.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the invention. The various appearances “an embodiment,” “one embodiment,” or “some embodiments” are not necessarily all referring to the same embodiments.

If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Those skilled in the art having the benefit of this disclosure will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. An apparatus comprising:
a thermally conductive base having a center; and
a plurality of folded fins coupled to the base so as to be oriented substantially radial to the center of the base.

2. The apparatus of claim 1 further comprising:
the plurality of folded fins being brazed to the base.

3. The apparatus of claim 1 wherein:
the plurality of folded fins comprise a monolithic folded strip.

4. The apparatus of claim 3 further comprising:
a plurality of monolithic folded strips coupled together, each comprising a plurality of folded fins.

5. The apparatus of claim 1 wherein:
the plurality of folded fins comprise a metallic composition.

6. The apparatus of claim 5 wherein:
the metallic composition of the folded fins comprises aluminum.

7. The apparatus of claim 5 wherein:
the base comprises a metallic composition.

8. The apparatus of claim 7 wherein:
the metallic composition of the base comprises copper.

9. The apparatus of claim 8 wherein:
the metallic composition of the folded fins comprises aluminum.

10. The apparatus of claim 1 wherein:
the base comprises a center portion and an outer portion which is thinner than the center portion.

11. The apparatus of claim 10 wherein:
the center portion comprises a raised portion having a substantially conical shape which extends within a dimension of the folded fin member.

12. The apparatus of claim 11 wherein:
the raised portion of the base comprises a plurality of posts separated by airflow channels.

13. An apparatus comprising:
a thermally conductive base;
a folded fin member coupled to the base and including a plurality of folded fins arranged substantially radially to the base; and
a fan coupled to at least one of the base and the folded fin member.

14. The apparatus of claim 13 wherein:
the fan is disposed substantially within a dimension of the folded fin member.

15. The apparatus of claim 13 wherein:
the fan is disposed substantially without a dimension of the folded fin member.

16. The apparatus of claim 13 further comprising:
a cap coupled to at least one of the base and the folded fin member, wherein the folded fin member is disposed between the base and the cap.

17. The apparatus of claim 16 wherein:
the base comprises a raised central portion.

18. The apparatus of claim 17 wherein:
the raised central portion of the base has a substantially conical shape.

19. The apparatus of claim 17 wherein:
the raised central portion comprises a plurality of posts separated by a plurality of airflow channels.

20. An apparatus comprising:
a plurality of concentrically disposed rings, each ring including,
a plurality of folded fins each oriented substantially radially within the apparatus.

21. The apparatus of claim 20 further comprising:
a base to which the folded fins are coupled.

22. The apparatus of claim 20 wherein:
the plurality of folded fins of a first ring of the plurality of concentrically disposed rings has a first intra-fin spacing at an outer circumference of the first ring; and
the plurality of folded fins of a second ring of the plurality of concentrically disposed rings has a second intra-fin spacing at an inner circumference of the second ring, wherein the second intra-fin spacing is closer than the first intra-fin spacing.

23. The apparatus of claim 20 wherein:
the plurality of folded fins of an outer ring of the plurality of concentrically disposed rings comprises a greater number of folded fins than the plurality of folded fins of an inner ring of the plurality of concentrically disposed rings.

24. The apparatus of claim 20 wherein:
the folded fins of first and second adjacent rings of the plurality of concentrically disposed rings are disposed such that the folded fins of the first ring are substantially non-aligned with the folded fins of the second ring.

25. An apparatus comprising:
a first plurality of fins each disposed substantially radially within the apparatus and extending to a first distance from a radial center of the first plurality of fins; and
a second plurality of fins each disposed substantially radially within the apparatus and extending to a second distance from the radial center; wherein
the fins of the second plurality of fins are interspersed among the first plurality of fins; and
the second distance is greater than the first distance.

26. The apparatus of claim 25 wherein:
the fins of the first plurality and the fins of the second plurality are disposed alternately.

27. The apparatus of claim 25 wherein:
the fins of the first plurality and the fins of the second plurality comprise a monolithic structure.

28. The apparatus of claim 27 wherein:
the fins of the first plurality and the fins of the second plurality comprise fins folded from a strip having a serrated edge.

29. The apparatus of claim 28 wherein:
the serrated edge has a substantially square tooth configuration.

30. The apparatus of claim 29 wherein:
the fins of the first plurality are formed from protruding portions of the square tooth configuration; and
the fins of the second plurality are formed from non-protruding portions of the square tooth configuration.

31. The apparatus of claim 30 wherein:
the fins are formed by fold pairs, each fold pair surrounding a transition from one of the protruding portion and the non-protruding portion to the other.

32. The apparatus of claim 28 wherein:
the serrated edge has a substantially sinusoidal configuration.

33. A method of manufacturing a heat sink, the method comprising:
folding a strip of thermally conductive material into a first plurality of folded fins;
thermally coupling the plurality of folded fins to a thermally conductive base in a radial arrangement.

34. The method of claim 33 further comprising: prior to coupling the first plurality of folded fins to the thermally conductive base, bending the folded strip around a mandrel to give the fins the radial arrangement.

35. The method of claim 33 wherein:
the thermally coupling the first plurality of folded fins to the thermally conductive base comprises brazing bottom segments of the fins to the base.

36. The method of claim 33 further comprising:
coupling a cap to the first plurality of folded fins in a configuration such that the folded fins are disposed between the base and the cap.

37. The method of claim 33 further comprising:
coupling a fan to the base.

38. The method of claim 37 further comprising:
disposing the fan within the fins.

39. The method of claim 33 further comprising:
fabricating the base to give the base a center portion having a greater thickness than an outer portion of the base.

40. The method of claim 39 further comprising:
fabricating the center portion of the base to have a substantially conical shape to extend within the fins.

41. The method of claim 40 further comprising:
fabricating the center portion to include a plurality of posts and a plurality of airflow channels between the posts.

42. The method of claim 33 further comprising:
folding a second strip into a second plurality of folded fins; and
thermally coupling the second plurality of folded fins to the thermally conductive base, disposed concentrically about the first plurality of folded fins.

43. The method of claim 42 further comprising:
spacing the folded fins of the second plurality to have a spacing at an inner circumference of the second plurality which is tighter than an outer circumference spacing of the folded fins of the first plurality.

44. The method of claim 43 further comprising:
prior to the thermally coupling the second plurality of folded fins to the thermally conductive base,
aligning the second plurality of folded fins with the first plurality of folded fins to substantially minimize instances where given ones of the first plurality are in radial alignment with given ones of the second plurality.

45. The method of claim 33 further comprising:
serrating an edge of the strip which forms an inner circumference of the first plurality of folded fins.

46. The method of claim 45 wherein:
the serrating comprises manufacturing the strip to give the edge a substantially square tooth pattern.

47. The method of claim 46 wherein:
the serrating comprises manufacturing the strip to give the edge a substantially sinusoidal tooth pattern.

48. The method of claim 45 wherein:
the folding comprises creating a plurality of fold pairs, wherein alternating ones of the fold pairs form laterally extending top portions of the folded fins and laterally extending bottom portions of the folded fins, respectively.

49. The method of claim 48 wherein:
the creating the plurality of fold pairs comprises encompassing serrations of the edge within fold pairs.

50. The method of claim 48 wherein:
the thermally coupling the plurality of folded fins to the thermally conductive base comprises coupling the laterally extending bottom portions of the folded fins to the base.

51. The method of claim 50 wherein:
the coupling the laterally extending bottom portions of the folded fins to the base comprises brazing.

52. The method of claim 50 wherein:
the coupling the laterally extending bottom portions of the folded fins to the base comprises affixing with epoxy.

53. A method of cooling a microelectronic device, the method comprising:
conducting heat from the microelectronic device through a base thermally coupled to the microelectronic device; and
conducting heat from the base through a first plurality of radial folded fins thermally coupled to the base.

54. The method of claim 53 further comprising:
blowing air over the first plurality of radial folded fins by a fan coupled to at least one of the base and the plurality of radial folded fins.

55. The method of claim 53 further comprising:
blowing air over the first plurality of radial folded fins; and
directing the air radially outward across the first plurality of radial folded fins by a substantially conical raised center portion of the base.

56. The method of claim 55 further comprising:
conducting heat from the base to the air by a plurality of posts of the substantially conical raised center portion of the base.

57. The method of claim 53 further comprising:
conducting heat from the base through a second plurality of radial folded fins coupled to the base and arranged concentrically with the first plurality of radial folded fins.

58. The method of claim 57 wherein the first and second pluralities of radial folded fins are disposed in a first ring and a second ring, respectively, and the second ring is disposed concentrically outside the first ring, the method further comprising:
reinitiating boundary layer development at the second ring.

59. The method of claim 57 wherein the first and second pluralities of radial folded fins are alternately interspersed, and the method further comprises:
as it moves radially outward, the air encountering the first plurality of radial folded fins before it encounters the second plurality of radial folded fins.
